(19) United States
(12) Patent Application Publication
(10) Pub. No.: US 2017/0244362 A1
(43) Pub. Date: Aug. 24, 2017

(54) DUAL-FREQUENCY-OUTPUT CRYSTAL CONTROLLED OSCILLATOR

(71) Applicant: NIHON DEMPA KOGYO CO., LTD., Tokyo (JP)

(72) Inventors: Shigeyoshi MURASE, Saitama (JP); Masahiro KASHIWAMURA, Saitama (JP)

(73) Assignee: NIHON DEMPA KOGYO CO., LTD., Tokyo (JP)

(21) Appl. No.: 15/401,101

(22) Filed: Jan. 9, 2017

(30) Foreign Application Priority Data
Feb. 22, 2016 (JP) 2016-031192

(51) Int. Cl. H03B 5/32; H03L 7/18; H03L 1/00

(52) U.S. Cl. CPC H03B 5/32; H03L 1/00; H03L 7/18; H03B 2200/008

(57) ABSTRACT

A dual-frequency-output crystal controlled oscillator includes a crystal resonator, an oscillator circuit, a first output terminal, a second output terminal, and a selection circuit. The crystal resonator includes an input terminal for measurement and an output terminal for measurement. The oscillator circuit is configured to amplify an output of the crystal resonator; a first output terminal configured to output a first frequency based on an output from the oscillator circuit. The second output terminal is configured to output a second frequency lower than the first frequency based on the output from the oscillator circuit. The selection circuit is configured to turn on/off an output of the first frequency. The input terminal for measurement is disposed such that a distance between the input terminal for measurement and the second output terminal is longer than a distance between the input terminal for measurement and the first output terminal.

### CROSS-REFERENCE TO RELATED APPLICATIONS

This application is based on and claims priority under 35 U.S.C.§119 to Japanese Patent Application No. 2016-031192, filed on Feb. 22, 2016, the entire content of which is incorporated herein by reference.

### TECHNICAL FIELD

This disclosure relates to a crystal controlled oscillator that outputs two different oscillation frequencies, in particular, a dual-frequency-output crystal controlled oscillator configured such that the respective oscillation frequencies are less likely to be affected.

### DESCRIPTION OF THE RELATED ART

### Conventional Crystal Controlled Oscillator: FIG. 9

The following describes a conventional crystal controlled oscillator with reference to FIG. 9. FIG. 9 is a block diagram of a configuration of the conventional crystal controlled oscillator. As illustrated in FIG. 9, the conventional crystal controlled oscillator includes a crystal resonator 1, an oscillator circuit 2, a dividing circuit or a Phase Locked Loop (PLL) circuit (a dividing circuit/PLL) 5, a buffer 3′, a selection circuit 6, and an output terminal 7′.

In the conventional crystal controlled oscillator, a frequency signal oscillated in the crystal resonator 1 is amplified by the oscillator circuit 2, divided in the dividing circuit/PLL 5, and output from the output terminal 7′ via the buffer 3′. The selection circuit 6 controls the output from the buffer 3′ to be turned on/off by on on/off signals from a control terminal.

In the conventional oscillator, a dual-frequency-output crystal controlled oscillator (a dual-mode crystal controlled oscillator) that oscillates at different frequencies has been developed.

### RELATED TECHNIQUE

As pertaining prior art, there are Japanese Unexamined Patent Application Publication No. 2001-156547 “MULTI-OUTPUT OSCILLATOR” (Matsushita Electric Industrial Co., Ltd., Patent Literature 1), Japanese Unexamined Patent Application Publication No. 2005-303411 “OSCILLATOR CIRCUIT” (Toyo Communication Equipment Co., Ltd., Patent Literature 2), Japanese Unexamined Patent Application Publication No. 2014-236466 “DUAL-MODE CRYSTAL CONTROLLED OSCILLATOR” (NIHON DEMPA KOGYO CO., LTD., Patent Literature 3), and Japanese Unexamined Patent Application Publication No. 2015-207856 “SEMICONDUCTOR INTEGRATED CIRCUIT, OSCILLATOR, ELECTRONIC APPARATUS, AND MOVING OBJECT” (SEIKO EPSON CORPORATION, Patent Literature 4).

Patent Literature 1 discloses a configuration in which a first output terminal and a second output terminal are formed on a bottom surface of a package so as to have a ground terminal in between in a multi-output oscillator. Patent Literature 2 discloses that rectangular wave signals having different phases from one another by 180° are output from a first output terminal and a second output terminal in an oscillator circuit.

Patent Literature 3 discloses a configuration in which a frequency output in MHz band is turned on/off in a state where a signal for a clock (32.768 kHz) is output, and two output terminals are disposed so as not to be adjacent in a dual-mode crystal controlled oscillator. Patent Literature 4 discloses a configuration in which a plurality of output terminals are formed on a top surface of a package in an oscillator.

The conventional dual-frequency-output crystal controlled oscillator described above, however, has a problem with a configuration in which an input terminal (an XT terminal) and an output terminal (an XTN terminal) of the crystal resonator are disposed in the package to measure a property of the crystal resonator. In such configuration, when one of the dual-frequency outputs is a frequency in the MHz band while the other is a frequency in the kHz band, the output terminal of the kHz band frequency and the XT terminal form a parasitic capacitance. When the kHz band frequency is fed back to the XT terminal, the kHz band frequency interferes with the MHz band frequency to deteriorate a phase noise characteristic of the MHz output.

While Patent Literature 1 discloses a configuration configured to dispose the first output terminal and the second output terminal on the bottom surface of the package so as to have the ground terminal in between, this configuration is not enough to minimalize the outputs from each of the output terminals affecting one another. In Patent Literature 2, a configuration simply outputs the outputs from the oscillator circuit as signal waveforms having phases different by 180° with PECL elements. This is not configured to selectively output either of the outputs.

In Patent Literature 3, the two output terminals are disposed so as not to be adjacent, this configuration does not minimalize the outputs from the respective output terminals affecting one another.

While in Patent Literature 4, the plurality of output terminals are formed on the top surface of the package, this configuration merely disposes the plurality of output terminals in a peripheral area of the top surface of the package.

A need thus exists for a dual-frequency-output crystal controlled oscillator which is not susceptible to the drawback mentioned above.

### SUMMARY

According to an aspect of this disclosure, there is provided a dual-frequency-output crystal controlled oscillator that includes a crystal resonator, an oscillator circuit, a first output terminal, a second output terminal, and a selection circuit. The crystal resonator includes an input terminal for measurement and an output terminal for measurement. The oscillator circuit is configured to amplify an output of the crystal resonator; a first output terminal configured to output a first frequency based on an output from the oscillator circuit. The second output terminal is configured to output a second frequency lower than the first frequency based on the output from the oscillator circuit. The selection circuit is configured to turn on/off an output of the first frequency. The input terminal for measurement is disposed such that a distance between the input terminal for measurement and the second output terminal is longer than a distance between the input terminal for measurement and the first output terminal.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a block diagram of a configuration of a dual-frequency-output crystal controlled oscillator according to an embodiment of this disclosure;

FIG. 2A is an explanatory drawing illustrating a left side surface of a package of an oscillator;

FIG. 2B is an explanatory drawing illustrating a bottom surface of the package of the oscillator;

FIG. 2C is an explanatory drawing illustrating a right side surface of the package of the oscillator;

FIG. 3 is a diagram illustrating a phase noise characteristic when a distance between a kHz terminal and an XT terminal is far;

FIG. 4 is a diagram illustrating a phase noise characteristic when the distance between the kHz terminal and the XT terminal is close;

FIG. 5 is a block diagram of a configuration of a crystal controlled oscillator according to a first application example;

FIG. 6 is a block diagram of a configuration of a crystal controlled oscillator according to a second application example;

FIG. 7 is a block diagram of a configuration of a crystal controlled oscillator according to a third application example;

FIG. 8 is a block diagram of a configuration of a crystal controlled oscillator according to a fourth application example; and

FIG. 9 is a block diagram of a configuration of a conventional crystal controlled oscillator.

### DETAILED DESCRIPTION

The following describes embodiments of this disclosure with reference to the drawings.

### Outline of Embodiment

A dual-frequency-output crystal controlled oscillator according to the embodiment of this disclosure includes: a crystal resonator including an input terminal for measurement and an output terminal for measurement; an oscillator circuit configured to amplify an output of the crystal resonator; a first output terminal configured to output a first frequency based on an output from the oscillator circuit; a second output terminal configured to output a second frequency lower than the first frequency based on an output from the oscillator circuit; and a selection circuit configured to turn on/off an output of the first frequency. The input terminal for measurement is disposed such that a distance between the input terminal for measurement and the second output terminal is longer than a distance between the input terminal for measurement and the first output terminal. Therefore, this disclosure has an effect to decrease parasitic capacitance between the input terminal for measurement and the second output terminal to achieve a good phase noise characteristic of the first frequency.

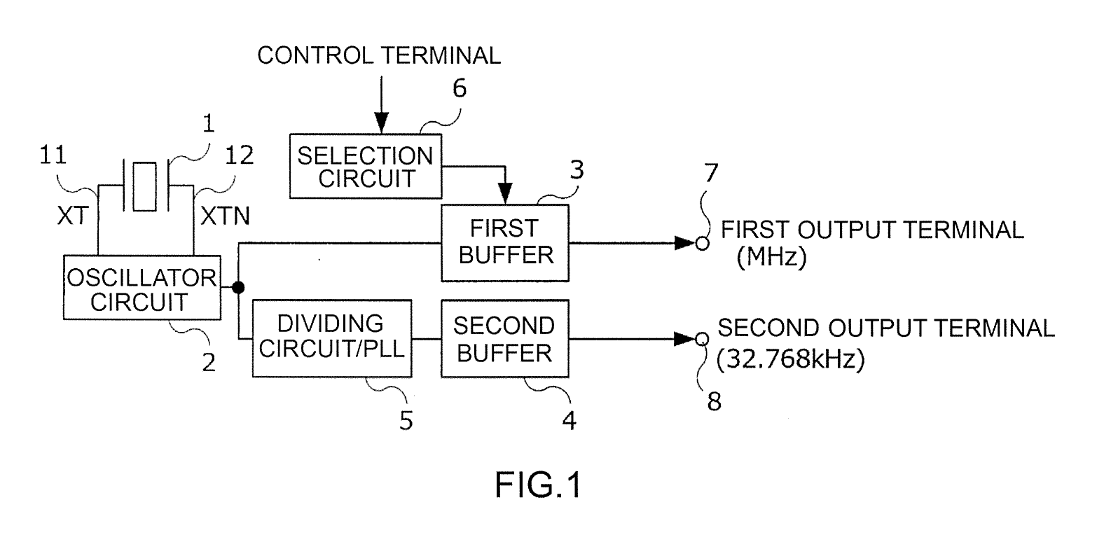

### The Oscillator: FIG. 1

The following describes a dual-frequency-output crystal controlled oscillator according an embodiment of this disclosure with reference to FIG. 1. FIG. 1 is a block diagram of a configuration of the dual-frequency-output crystal controlled oscillator according to the embodiment of this disclosure. The dual-frequency-output crystal controlled oscillator (this oscillator) according to the embodiment of this disclosure basically includes a crystal resonator 1, an oscillator circuit 2, a first buffer 3, a second buffer 4, a dividing circuit or a Phase Locked Loop (PLL) circuit (a dividing circuit/PLL) 5, a selection circuit 6, a first output terminal 7 (also referred to as a “MHz terminal 7”), and a second output terminal 8 (also referred to as a “kHz terminal 8”), as illustrated in FIG. 1.

### Each Unit: FIG. 1

The following specifically describes each of units of this oscillator. An AT-cut quartz-crystal vibrating piece is mainly used for the crystal resonator 1. The oscillator circuit 2 inputs a signal to the crystal resonator 1, and then the crystal resonator 1 outputs a specific oscillation frequency to the oscillator circuit 2. The oscillation frequency is a frequency in the MHz band. In this oscillator, an input terminal and an output terminal of the crystal resonator 1 are disposed in a package to measure a property of the crystal resonator 1. A frequency of the AT-cut crystal resonator 1 is inversely proportional to a thickness of the AT-cut quartz-crystal vibrating piece; therefore, the frequency of the AT-cut crystal resonator 1 is mainly adjusted, for example, by adjusting the thickness of the AT-cut quartz-crystal vibrating piece.

The oscillator circuit 2 amplifies the frequency oscillated by the crystal resonator 1 to output the frequency to the first buffer 3 and the dividing circuit/PLL 5. The first buffer 3 prevents a high frequency signal from returning to an input side from an output side as well as continues outputting the frequency or stops outputting the frequency in accordance with a selection signal from the selection circuit 6. The frequency from the first buffer 3 is output to the first output terminal 7. From the first output terminal 7, the frequency in the MHz band is output.

The dividing circuit/PLL 5 divides the frequency signal output from the oscillator circuit 2 to output the divided frequency signal output to the second buffer 4. The second buffer 4 prevents the high frequency signal from returning to the input side from the output side. The frequency from the second buffer 4 is output to the second output terminal 8. From the second output terminal 8, the frequency for a clock of 32.768 kHz is output.

The selection circuit 6 controls the output of the first buffer 3 in accordance with on/off signals from a control terminal. Specifically, when the on signal is input from the control terminal, the selection circuit 6 outputs the selection signal to continue outputting from the first buffer 3 to the first buffer 3. This causes the first buffer 3 to output the frequency signal to the first output terminal 7. When the off signal is input from the control terminal, the selection circuit 6 outputs the selection signal to stop outputting from the first buffer 3 to the first buffer 3. This causes the first buffer 3 not to output the frequency signal to the first output terminal 7.

This oscillator selectively outputs the frequency in the MHz band from the first output terminal 7 while always outputting the frequency for the clock from the second output terminal 8. For example, in the case where this oscillator is used in a wireless communication using Wi-Fi, the selection circuit 6 selects to turn on the output to output the frequency in the MHz band, and the frequency in the MHz band us used. Not always outputting, but selectively outputting the MHz signal ensures reducing power consumption.

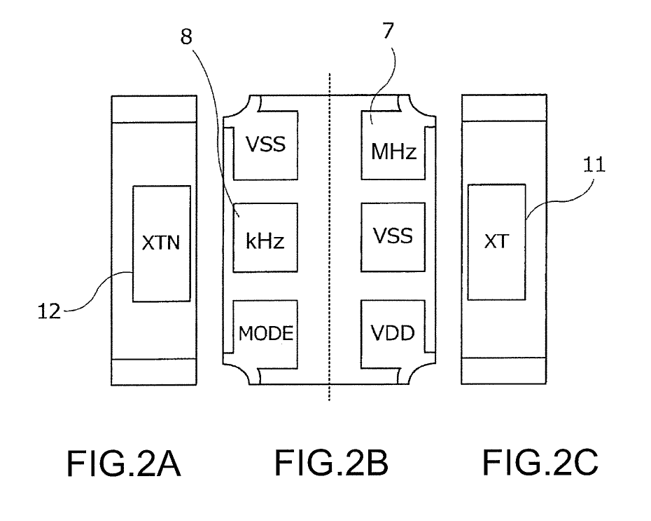

Bottom Surface and Side Surfaces of this Oscillator: FIG. 2A to FIG. 2C

Next, a bottom surface and side surfaces of the package of this oscillator will be described with reference to FIG. 2A to FIG. 2C. FIG. 2A is an explanatory drawing illustrating the left side surface of the package of this oscillator; FIG. 2B is an explanatory drawing illustrating the bottom surface of the package of this oscillator; FIG. 2C is an explanatory drawing illustrating the right side surface of the package of this oscillator. As illustrated in FIG. 2B, the bottom surface includes six terminals. At a left side of a dotted line illustrated in a vertical direction in the center of the bottom surface, a “VSS” terminal, the “kHz” terminal 8, and a “MODE” terminal are disposed. At a right side of the dotted line, the “MHz” terminal 7, a “VSS” terminal, and a “VDD” terminal are disposed.

The “VSS” terminals are ground (GND) terminals The “VDD” terminal is a terminal to which a supply voltage is applied. The “MHz” terminal 7 is a terminal that outputs the frequency in the MHz band and corresponds to the first output terminal 7 in FIG. 1. The “kHz” terminal 8 is a terminal that outputs the frequency of 32.768 kHz and corresponds to the second output terminal 8 in FIG. 1. The “MODE” terminal is a terminal to which the control signal to turn on/off (continue/stop) the output from the first output terminal 7 is input and corresponds to the control terminal in FIG. 1.

As illustrated in FIG. 2C, an XT terminal 11 is formed on a right side of to the bottom surface. As illustrated in FIG. 2A, an XTN terminal 12 is formed on a left side of the bottom surface. Since the XT terminal 11 is formed on the right side surface, a distance between the XT terminal 11 and the kHz terminal 8 is long compared with a distance between the XT terminal 11 and the MHz terminal 7. Thus, a parasitic capacitance is less likely to be formed between the kHz terminal 8 and the XT terminal 11, and thereby the output signal of the kHz terminal 8 does not affect the XT terminal 11.

The frequency of the signal output from the MHz terminal 7 is the high frequency compared with the frequency of the signal input to the XT terminal 11. Thus, even though the distance between the XT terminal 11 and the MHz terminal 7 is close, the effect is small compared with a case where the kHz terminal 8 is close.

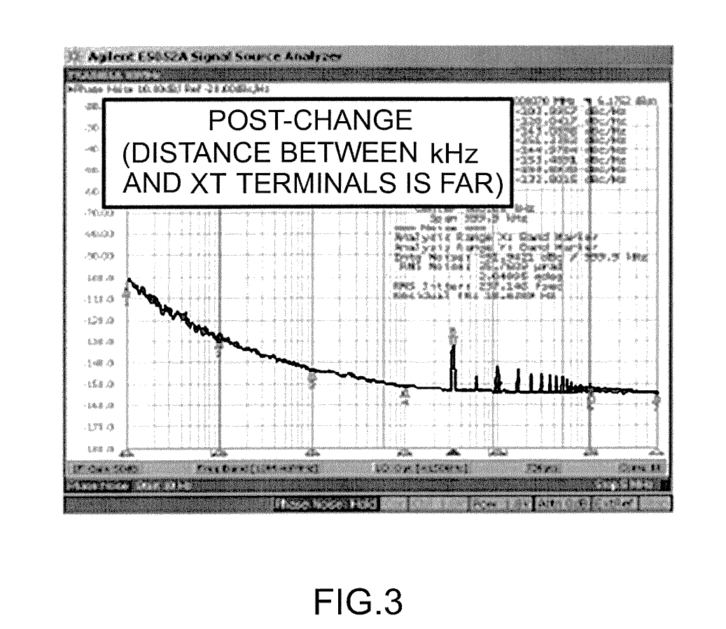

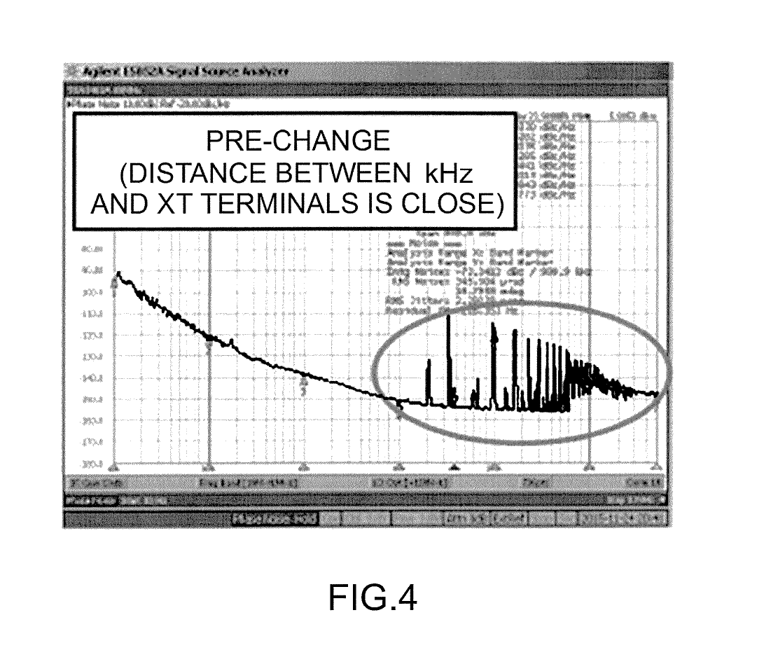

Output Phase Noise of this Oscillator: FIG. 3 and FIG. 4

Next, a phase noise characteristic of the frequency in the MHz band in this oscillator will be described with reference to FIG. 3 and FIG. 4. FIG. 3 is a diagram illustrating the phase noise characteristic when the distance between the kHz terminal and the XT terminal is far. FIG. 4 is a diagram illustrating the phase noise characteristic when the distance between the kHz terminal and the XT terminal is close. In FIG. 3 and FIG. 4, a horizontal axis indicates the frequency and a vertical axis indicates the phase noise.

In the case where the distance between the kHz terminal and the XT terminal 11 is long like this oscillator, the frequency output from the MHz terminal 7 has the phase noise characteristic shown in FIG. 3. In the configuration where the distance between the kHz terminal and the XT terminal 11 is short, the frequency output from the MHz terminal 7 has the phase noise characteristic shown in FIG. 4.

In the case where the distance between the kHz terminal and the XT terminal 11 is short, the phase noise occurs more in the high frequency as circled by an ellipse in FIG. 4. Therefore, the phase noise characteristic is better when the distance between the kHz terminal and the XT terminal 11 is long. Here, the configuration where the distance between the kHz terminal and the XT terminal 11 is short falls into, for example, a case where the positions of the kHz terminal 8 and the MHz terminal 7 are exchanged in FIG. 2A to FIG. 2C.

Effect of this Oscillator

With this oscillator, since the XT terminal 11 is positioned farther from the kHz terminal 8 than that from the MHz terminal 7, the parasitic capacitance between the XT terminals 11 and the kHz terminal 8 can be decreased. This is effective to achieve a good phase noise characteristic of the frequency output from the MHz terminal 7.

### APPLICATION EXAMPLES

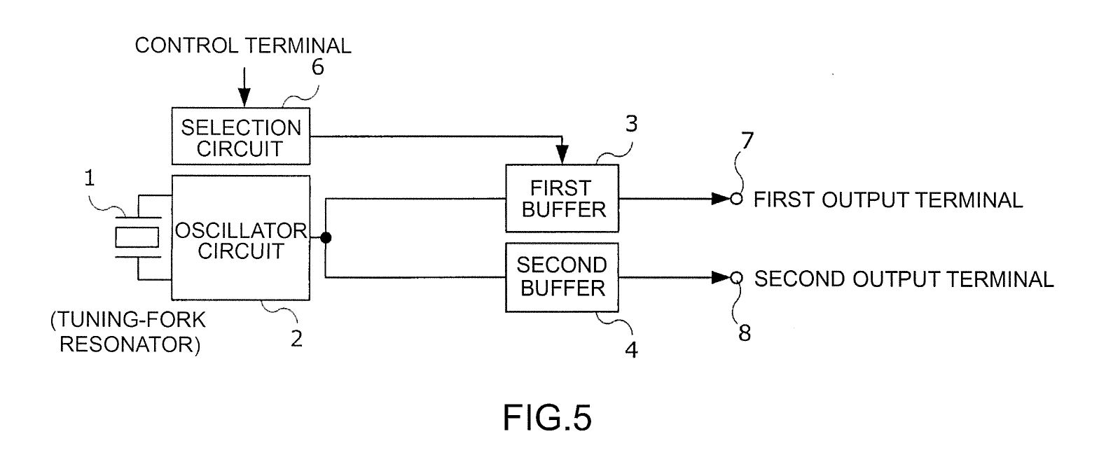

Next, application examples will be described with reference to FIG. 5 to FIG. 8.

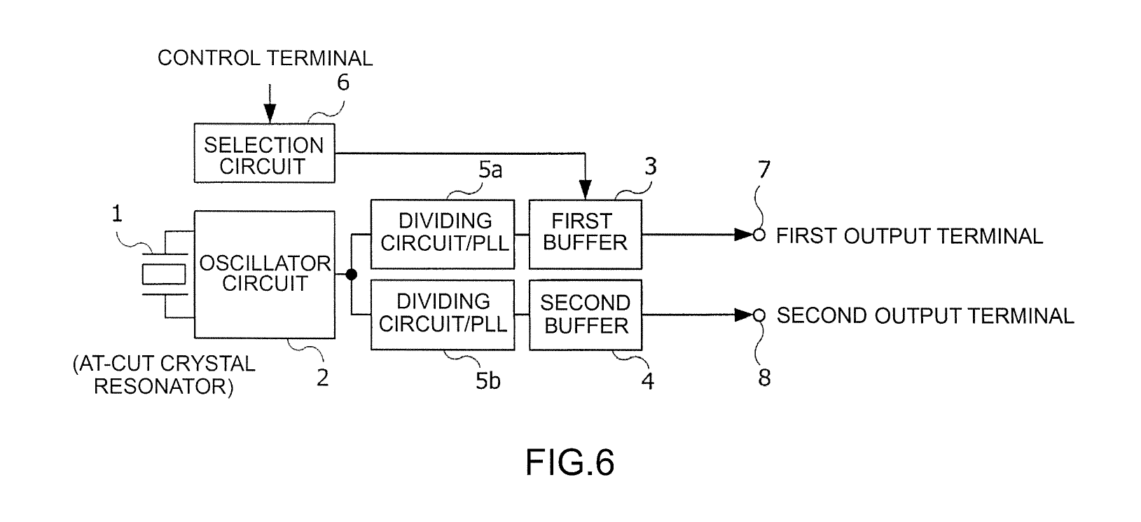

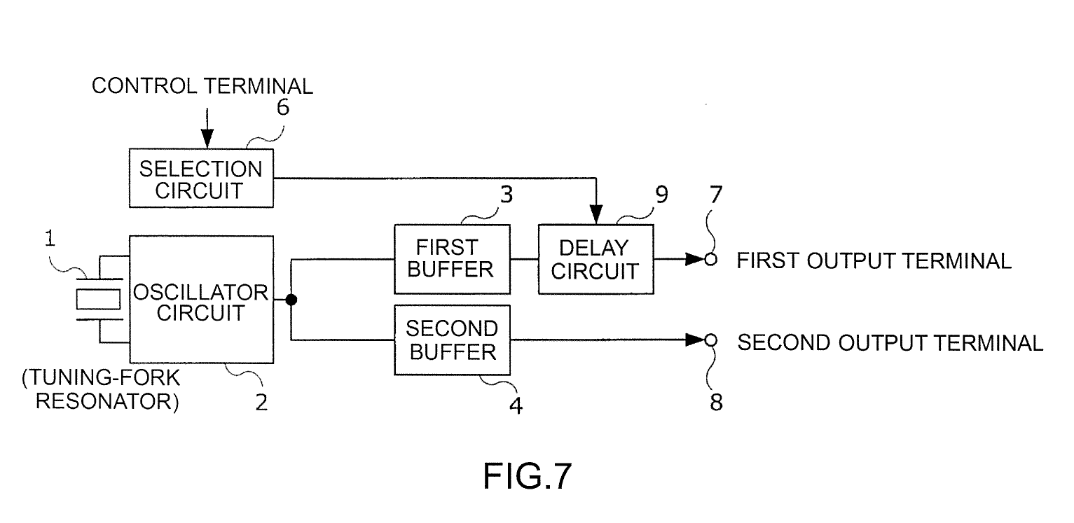

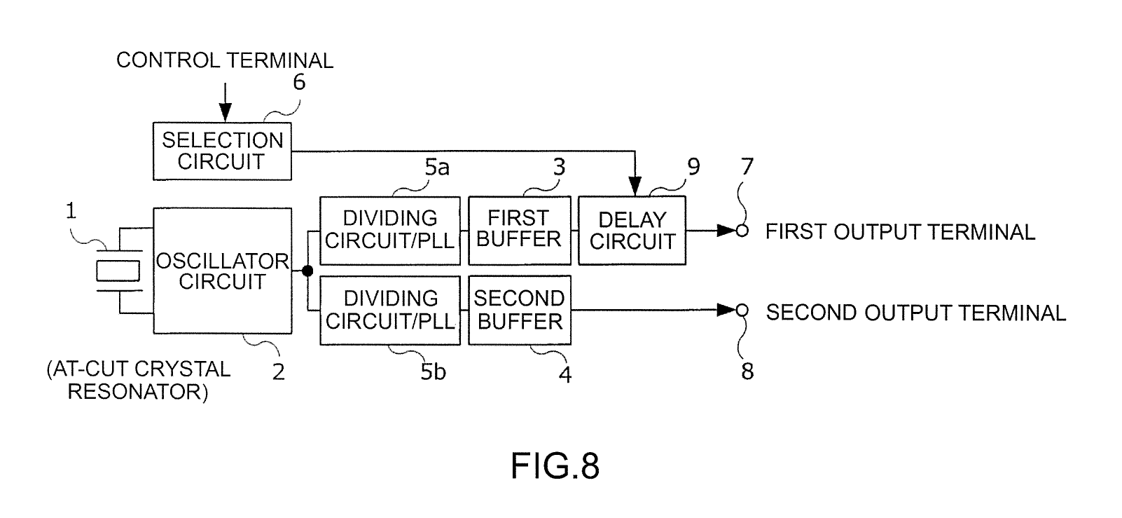

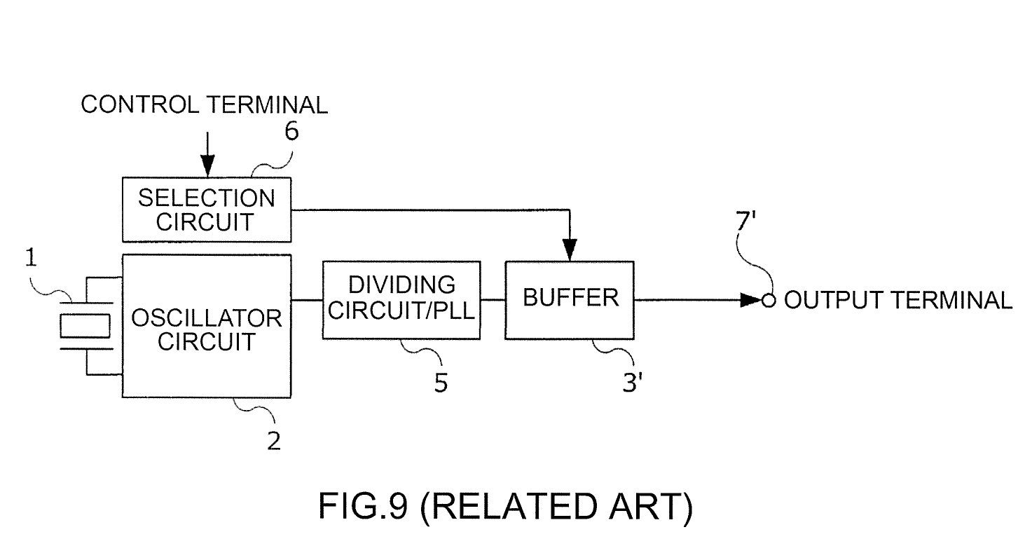

FIG. 5 is a block diagram of a configuration of a crystal controlled oscillator according to a first application example. FIG. 6 is a block diagram of a configuration of a crystal controlled oscillator according to a second application example. FIG. 7 is a block diagram of a configuration of a crystal controlled oscillator according to a third application example. FIG. 8 is a block diagram of a configuration of a crystal controlled oscillator according to a fourth application example.

### First Application Example

### FIG. 5

The crystal controlled oscillator of the first application example includes the crystal resonator 1, the oscillator circuit 2, the first buffer 3, the second buffer 4, the selection circuit 6, the first output terminal 7, and the second output terminal 8 as illustrated in FIG. 5.

In the first application example, the crystal resonator 1 is assumed to be a tuning-fork resonator. The output signal from the oscillator circuit 2 is branched to be input to the first buffer 3 and the second buffer 4. When the on signal is input from the control terminal, the selection circuit 6 outputs the selection signal to continue outputting the frequency signal from the first buffer 3 to the first buffer 3. Then, the first buffer 3 outputs the frequency signal to the first output terminal 7.

When the off signal is input from the control terminal, the selection circuit 6 outputs the selection signal to stop outputting the frequency signal from the first buffer 3 to the first buffer 3. Then, the first buffer 3 does not output the frequency signal to the first output terminal 7. The signal of the frequency is always output from the second output terminal 8 via the second buffer 4.

According to the first application example, the identical frequency signals can be selectively output from the first output terminal 7 and always output from the second output terminal 8. This has an effect that the identical frequency signals can be used according to a purpose.

### Second Application Example

### FIG. 6

A crystal controlled oscillator of the second application example includes the crystal resonator 1, the oscillator circuit 2, dividing circuit/PLLs 5a and 5b, the first buffer 3, the second buffer 4, the selection circuit 6, the first output terminal 7, and the second output terminal 8, as illustrated in FIG. 6.

In the second application example, the crystal resonator 1 is assumed to be an AT-cut crystal resonator. The output signal from the oscillator circuit 2 is branched, and divided in the dividing circuit/PLLs 5a and 5b to be input to the first buffer 3 and the second buffer 4. In the dividing circuit/PLLs 5a and 5b, the output signal is divided to be respective desired frequencies. Operations of the selection circuit 6, the first buffer 3, the second buffer 4, the first output terminal 7, and the second output terminal 8 are similar to those of the first application example.

According to the second application example, different frequency signals can be selectively output from the first output terminal 7 and always output from the second output terminal 8. This has an effect that the different frequency signals can be used according to a purpose.

### Third Application Example

### FIG. 7

A crystal controlled oscillator of the third application example includes the crystal resonator 1, the oscillator circuit 2, the first buffer 3, the second buffer 4, the selection circuit 6, the first output terminal 7, the second output terminal 8, and a delay circuit 9, as illustrated in FIG. 7.

In the third application example, the crystal resonator 1 is assumed to be a tuning-fork resonator. Basic operations are similar to those of the first application example; however, the difference is that the delay circuit 9 disposed in a latter part of the first buffer 3 delays outputting the frequency signal to the first output terminal 7. In the third application example, while the selection circuit 6 controls the delay circuit 9 to control turning on/off the output of the frequency signal, the selection circuit 6 may control the first buffer 3.

According to the third application example, the identical frequency signals can be selectively output being delayed (in shifted phases) from the first output terminal 7 and always output from the second output terminal 8. This has an effect that the identical frequency signal can be used according to a purpose.

### Fourth Application Example

### FIG. 8

A crystal controlled oscillator of the fourth application example includes the crystal resonator 1, the oscillator circuit 2, the dividing circuit/PLLs 5a and 5b, the first buffer 3, the second buffer 4, the selection circuit 6, the first output terminal 7, the second output terminal 8, and the delay circuit 9, as illustrated in FIG. 8.

In the fourth application example, the crystal resonator 1 is assumed to be an AT-cut crystal resonator. Basic operations are similar to those of the second application example; however, the difference is that the delay circuit 9 disposed in the latter part of the first buffer 3 delays outputting the frequency signal to the first output terminal 7. In the fourth application example, while the selection circuit 6 controls the delay circuit 9 to control turning on/off the output of the frequency signal, the selection circuit 6 may control the first buffer 3.

According to the fourth application example, the different frequency signals can be selectively output being delayed (in shifted phases) from the first output terminal 7 and always output from the second output terminal 8. This has an effect that the different frequency signals can be used in accordance with a purpose.

This disclosure is appropriate for an dual-frequency-output crystal controlled oscillator in which the XT terminal is disposed such that the output terminal of the lower frequency of the dual frequency output is farther from the XT terminal than that from the output terminal of the higher frequency in order to decrease the parasitic capacitance to achieve a good phase noise characteristic of the higher frequency.

The discloser may be the dual-frequency-output crystal controlled oscillator that includes a dividing circuit or a PLL circuit configured to divide the output from the oscillator circuit so as to output the divided output to the second output terminal.

In the above-described dual-frequency-output crystal controlled oscillator, the first output terminal and the second output terminal may be disposed on a bottom surface of a package and the input terminal for measurement may be disposed on a side surface of the package.

The disclosure may be a dual-frequency-output crystal controlled oscillator that includes: a crystal resonator that includes an input terminal for measurement and an output terminal for measurement; an oscillator circuit configured to amplify an output of the crystal resonator; a first output terminal configured to output a first frequency based on an output from the oscillator circuit; a second output terminal configured to output a second frequency based on the output from the oscillator circuit; and a selection circuit configured to turn on/off an output of the first frequency.

The disclosure may a dual-frequency-output crystal controlled oscillator that includes a first dividing circuit or a first PLL circuit configured to divide the output from the oscillator circuit and output the divided output to the first output terminal and a second dividing circuit or a second PLL circuit configured to divide the output from the oscillator circuit and output the divided output to the second output terminal.

The disclosure may be a dual-frequency-output crystal controlled oscillator that includes a delay circuit configured to delay the output of the first frequency in the above-described dual-frequency-output crystal controlled oscillator.

In this disclosure, a dual-frequency-output crystal controlled oscillator includes a crystal resonator, an oscillator circuit, a first output terminal, a second output terminal, and a selection circuit. The crystal resonator includes an input terminal for measurement and an output terminal for measurement. The oscillator circuit is configured to amplify an output of the crystal resonator. The first output terminal is configured to output a first frequency based on an output from the oscillator circuit. The second output terminal is configured to output a second frequency lower than the first frequency based on the output from the oscillator circuit. The selection circuit is configured to turn on/off an output of the first frequency. The input terminal for measurement is disposed such that a distance between the input terminal for measurement and the second output terminal is longer than a distance between the input terminal for measurement and the first output terminal. Therefore, this disclosure has an effect to decrease parasitic capacitance between the input terminal for measurement and the second output terminal to achieve a good phase noise characteristic of the first frequency.

The principles, preferred embodiment and mode of operation of the disclosure have been described in the foregoing specification. However, the disclosure which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the disclosure. Accordingly, it is expressly intended that all such variations, changes and equivalents which fall within the spirit and scope of the disclosure as defined in the claims, be embraced thereby.

What is claimed is:

1. A dual-frequency-output crystal controlled oscillator comprising:
a crystal resonator that includes an input terminal for measurement and an output terminal for measurement;
an oscillator circuit configured to amplify an output of the crystal resonator;
a first output terminal configured to output a first frequency based on an output from the oscillator circuit;
a second output terminal configured to output a second frequency lower than the first frequency based on the output from the oscillator circuit; and
a selection circuit configured to turn on/off an output of the first frequency, wherein
the input terminal for measurement is disposed such that a distance between the input terminal for measurement and the second output terminal is longer than a distance between the input terminal for measurement and the first output terminal.

2. The dual-frequency-output crystal controlled oscillator according to claim 1, further comprising
a dividing circuit or a PLL circuit configured to divide the output from the oscillator circuit and output the divided output to a side of the second output terminal.

3. The dual-frequency-output crystal controlled oscillator according to claim 1, wherein:
the first output terminal and the second output terminal are disposed on a bottom surface of a package, and
the input terminal for measurement is disposed on a side surface of the package.

4. A dual-frequency-output crystal controlled oscillator comprising:
a crystal resonator that includes an input terminal for measurement and an output terminal for measurement;
an oscillator circuit configured to amplify an output of the crystal resonator;
a first output terminal configured to output a first frequency based on an output from the oscillator circuit;
a second output terminal configured to output a second frequency based on the output from the oscillator circuit; and
a selection circuit configured to turn on/off an output of the first frequency.

5. The dual-frequency-output crystal controlled oscillator according to claim 4, further comprising:
a first dividing circuit or a first PLL circuit configured to divide the output from the oscillator circuit and output the divided output to a side of the first output terminal; and
a second dividing circuit or a second PLL circuit configured to divide the output from the oscillator circuit and output the divided output to a side of the second output terminal.

6. The dual-frequency-output crystal controlled oscillator according to claim 4, further comprising
a delay circuit configured to delay the output of the first frequency.
